(19) United States
(12) Patent Application Publication
(10) Pub. No.: US 2022/0157573 A1
(43) Pub. Date: May 19, 2022

(54) EDGE RING AND SUBSTRATE PROCESSING APPARATUS

(71) Applicant: Tokyo Electron Limited, Tokyo (JP)

(72) Inventors: Junichi Sasaki, Kurokawa-gun (JP); Masashi Ikegami, Kurokawa-gun (JP); Mitsuaki Sato, Kurokawa-gun (JP); Kazuhiko Akahane, Kurokawa-gun (JP)

(21) Appl. No.: 17/454,308

(22) Filed: Nov. 10, 2021

(30) Foreign Application Priority Data
Nov. 13, 2020 (JP) 2020-189582

(51) Int. Cl. H01J 37/32

(52) U.S. Cl. CPC H01J 37/32642; H01J 37/32467

(57) ABSTRACT

An edge ring disposed around a processing target substrate includes a first member of an annular shape, which is made of a first material and has a first inclined portion at a lower portion of an inner peripheral side surface thereof; and a second member of an annular shape, which is made of a second material different from the first material and has a second inclined portion facing the first inclined portion, the second member being provided under the first member.

### CROSS-REFERENCE TO RELATED APPLICATION

This application claims the benefit of Japanese Patent Application No. 2020-189582 filed on Nov. 13, 2020, the entire disclosure of which is incorporated herein by reference.

### TECHNICAL FIELD

The various aspects and embodiments described herein pertain generally to an edge ring and a substrate processing apparatus.

### BACKGROUND

In a plasma processing for a substrate, an edge ring may be disposed along an edge of the substrate placed in a chamber set to a predetermined vacuum level. Due to the edge ring disposed in this way, the plasma processing can be performed uniformly within a surface of the substrate.

The plasma processing upon the substrate is performed in the state that the substrate and the edge ring disposed on an electrostatic chuck are attracted to and held by the electrostatic chuck by an electrostatic attraction force. Further in order to improve a heat transfer between the substrate and the electrostatic chuck and a heat transfer between the edge ring and the electrostatic chuck, a heat transfer gas such as a He gas is supplied into a gap between the electrostatic chuck and the substrate and into a gap between the electrostatic chuck and the edge ring.

Patent Document 1: Japanese Patent Laid-open Publication No. 2010-251723

### SUMMARY

In one exemplary embodiment, an edge ring disposed around a processing target substrate includes a first member of an annular shape, which is made of a first material and has a first inclined portion at a lower portion of an inner peripheral side surface thereof; and a second member of an annular shape, which is made of a second material different from the first material and has a second inclined portion facing the first inclined portion, the second member being provided under the first member.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a diagram illustrating an example of a substrate processing apparatus according to an exemplary embodiment;

FIG. 2 is a diagram illustrating an example configuration of an edge ring according to the exemplary embodiment;

FIG. 3 is a diagram illustrating examples of a gap between a first member and a second member on an inner peripheral side in an experimental example and comparative examples;

FIG. 4 is a diagram illustrating examples of experimental results in the experimental example and the comparative examples; and

FIG. 5 is a diagram illustrating comparative examples regarding processing precision.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

In the following description, an exemplary embodiment of an edge ring and a substrate processing apparatus according to the present disclosure will be described in detail with reference to the accompanying drawings. However, it should be noted that the present disclosure is not limited by the exemplary embodiment.

Generally, an edge ring is worn away as a plasma processing is performed. Since the edge ring formed of silicon carbide (SiC) (hereinafter also referred to as a SiC edge ring) has high plasma resistance, replacement frequency of the edge ring can be reduced. However, since the SiC edge ring has high rigidity, an attraction force by an electrostatic chuck may be reduced, so that a leak of the heat transfer gas may be increased. To solve this problem, it may be considered to attach silicon (Si) to an electrostatic chuck side of the edge ring as a member having lower rigidity than SiC in order to enhance the attraction force by improving followability of the edge ring to the electrostatic chuck. However, since a gap is formed at a boundary between SiC and Si, a reaction product may adhere to this gap. The reaction product in the gap is deposited with a lapse of a plasma processing time, and particles are generated as this reaction product is later peeled off. Thus, it is required to suppress the leakage of the heat transfer gas and the generation of particles while reducing the replacement frequency of the edge ring.

[Configuration of Substrate Processing Apparatus 100]

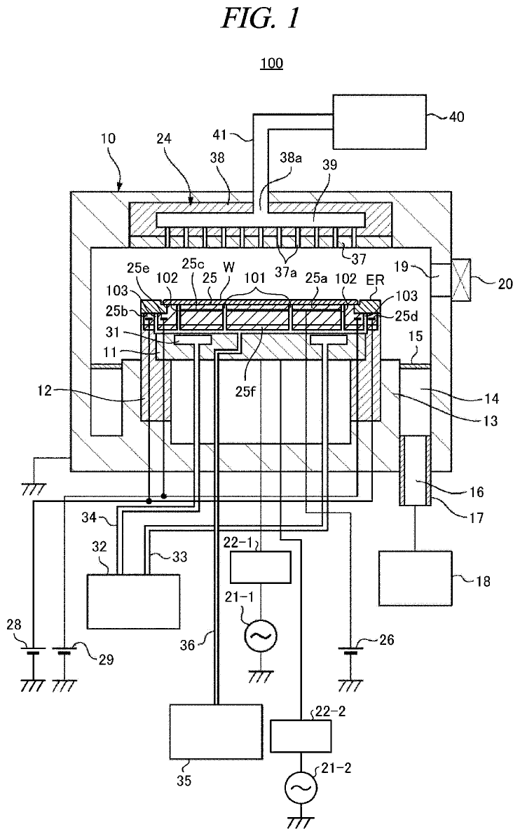

FIG. 1 is a diagram illustrating an example of a substrate processing apparatus according to an exemplary embodiment. A substrate processing apparatus 100 shown in FIG. 1 is a capacitively coupled plasma processing apparatus. The substrate processing apparatus 100 is equipped with a chamber 10 which is a metal processing vessel made of, by way of non-limiting example, aluminum or stainless steel. The chamber 10 is frame-grounded.

A disk-shaped susceptor 11 is horizontally disposed within the chamber 10. The susceptor 11 is disposed on a bottom surface of an electrostatic chuck 25 on which a semiconductor substrate (hereinafter, sometimes referred to as “wafer W”) as a processing target substrate and an edge ring ER are disposed. Further, the susceptor 11 serves as a lower electrode to which a high frequency voltage is applied. The susceptor 11 is made of, for example, aluminum and is supported by a cylindrical support 13 extending vertically upwards from a bottom of the chamber 10 with an insulating cylindrical holding member 12 therebetween.

An exhaust path 14 is formed between a sidewall of the chamber 10 and the cylindrical support 13, and an annular baffle plate 15 is disposed at an inlet or in the middle of the exhaust path 14. Further, an exhaust port 16 is provided at the bottom of the chamber 10, and an exhaust device 18 is connected to the exhaust port 16 via an exhaust pipe 17. The exhaust device 18 has a vacuum pump and decompresses a processing space provided by the chamber 10 to a required vacuum level. Further, the exhaust pipe 17 is provided with an APC (Automatic Pressure Control Valve), which automatically controls an internal pressure of the chamber 10. Further, a gate valve 20 configured to open or close a carry-in/out opening 19 for the wafer W is provided at the sidewall of the chamber 10.

High frequency power supplies 21-1 and 21-2 are electrically connected to the susceptor 11 via matching devices 22-1 and 22-2, respectively. The high frequency power supply 21-1 is configured to apply a high frequency voltage for plasma formation to the susceptor 11. Specifically, the high frequency power supply 21-1 applies a high frequency voltage of 27 MHz to 100 MHz to the susceptor 11, desirably, a high frequency voltage of, e.g., 40 MHz to the susceptor 11. Further, the high frequency power supply 21-2 applies, to the susceptor 11, a high frequency voltage for ion attraction into the wafer W. Specifically, the high frequency power supply 21-2 applies a high frequency voltage of 400 kHz to 40 MHz to the susceptor 11, desirably, a high frequency voltage of, e.g., 3 MHz to the susceptor 11. The matching device 22-1 matches an output impedance of the high frequency power supply 21-1 and an input impedance on the susceptor 11 side. The matching device 22-2 matches an output impedance of the high frequency power supply 21-2 and the input impedance on the susceptor 11 side.

The electrostatic chuck 25 is disposed on a top surface of the susceptor 11, and is configured to attract the wafer W and the edge ring ER disposed on the electrostatic chuck 25 by an electrostatic attraction force. The electrostatic chuck 25 has a circular plate-shaped central portion 25a, an annular outer peripheral portion 25b, and a disk-shaped base portion 25f having a larger diameter than the central portion 25a, and the central portion 25a is protruded higher than the outer peripheral portion 25b. Bottom surfaces of the central portion 25a and the outer peripheral portion 25b and a top surface of the base portion 25f are bonded to form the electrostatic chuck 25. The wafer W is placed on a top surface of the central portion 25a. The edge ring ER is disposed on a top surface of the outer peripheral portion 25b to surround the central portion 25a in a ring shape. Further, the central portion 25a is formed of a pair of dielectric films and an electrode plate 25c made of a conductive film and embedded between the pair of dielectric films. Meanwhile, the outer peripheral portion 25b is formed of a pair of dielectric films and electrode plates 25d and 25e each made of a conductive film and embedded between the pair of dielectric films. That is, the electrode plates 25c, 25d and 25e are provided within the electrostatic chuck 25. Within the electrostatic chuck 25, the electrode plate 25c is provided in a region corresponding to the wafer W. Within the electrostatic chuck 25, the electrode plates 25d and 25e are provided in a region corresponding to the edge ring ER.

A DC power supply 26 is electrically connected to the electrode plate 25c. A DC power supply 28 is electrically connected to the electrode plate 25d. A DC power supply 29 is electrically connected to the electrode plate 25e. The electrostatic chuck 25 attracts and holds the wafer W by a Coulomb force or a Johnson-Rabeck force generated by a DC voltage applied to the electrode plate 25c from the DC power supply 26. Further, the electrostatic chuck 25 attracts and holds the edge ring ER by a Coulomb force or a Johnson-Rabeck force generated by a DC voltage applied to the electrode plates 25d and 25e from the DC power supplies 28 and 29. That is, within the electrostatic chuck 25, an electrode for electrostatically attracting the wafer W is provided in a region at least partially overlapping with the wafer W, and an electrode for electrostatically attracting the edge ring ER is provided in a region at least partially overlapping with the edge ring ER, when FIG. 1 is viewed from the top.

As described above, the wafer W is disposed on the top surface of the central portion 25a of the electrostatic chuck 25. Further, the edge ring ER is disposed on the top surface of the outer peripheral portion 25b of the electrostatic chuck 25 to surround the central portion 25a in the ring shape. That is, the edge ring ER is disposed on the electrostatic chuck 25 so as to surround the wafer W. In addition, the bottom surface of the electrostatic chuck 25 and the top surface of the susceptor 11 are in contact with each other. Accordingly, the susceptor 11 and the electrostatic chuck 25 are formed as a placing table for placing the wafer W and the edge ring ER thereon.

An annular coolant path 31 extending in a circumferential direction is provided within the susceptor 11. A coolant (for example, cooling water) of a preset temperature is supplied from a chiller unit 32 into the coolant path 31 through pipelines 33 and 34 to be circulated therein, and a processing temperature of the wafer W on the electrostatic chuck 25 is controlled by a temperature of the coolant.

In addition, a heat transfer gas (e.g., a He gas) is supplied from a heat transfer gas supply 35 into a gap between the top surface of the electrostatic chuck 25 and a bottom surface of the wafer W and into a gap between the top surface of the electrostatic chuck 25 and a bottom surface of the edge ring ER through a gas supply pipe 36 and gas inlet holes 101, 102 and 103. The gas supply line 36 is disposed to penetrate the susceptor 11 and the base portion 25f of the electrostatic chuck 25. The gas inlet holes 101 and 102 connected to the gas supply line 36 are provided in the central portion 25a of the electrostatic chuck 25. The gas inlet hole 103 connected to the gas supply line 36 is provided in the outer peripheral portion 25b of the electrostatic chuck 25. In the outer peripheral portion 25b of the electrostatic chuck 25, the two electrode plates (the electrode plate 25d and the electrode plate 25e) are disposed such that the gas inlet hole 103 is positioned therebetween. A heat transfer between the wafer W and the electrostatic chuck 25 and a heat transfer between the edge ring ER and the electrostatic chuck 25 are improved by the heat transfer gas supplied from the heat transfer gas supply 35 through the gas supply line 36 and the gas inlet holes 101, 102 and 103.

A shower head 24 serving as an upper electrode of a ground potential is disposed at a ceiling of the chamber 10. The shower head 24 is equipped with an electrode plate 37 having a plurality of gas through holes 37a and an electrode supporting body 38 supporting the electrode plate 37. Further, a buffer room 39 is provided inside the electrode supporting body 38, and a gas supply line 41 from a processing gas supply 40 is connected to a gas inlet port 38a of the buffer room 39.

When a dry etching processing, for example, is performed in the substrate processing apparatus 100, the gate valve 20 is first opened, and the wafer W is carried into the chamber 10 to be placed on the electrostatic chuck 25. Then, as the processing gas, a mixed gas including, for example, a C₄F₈ gas, an O₂ gas and an Ar gas having a preset flow rate ratio is introduced into the chamber 10 from the processing gas supply 40 at a predetermined flow rate and a predetermined flow rate ratio. The internal pressure of the chamber 10 is regulated to a preset value by the exhaust device 18. Further, the DC voltage from the DC power supply 26 is applied to the electrode plate 25c, and the DC voltages from the DC power supplies 28 and 29 are respectively applied to the electrode plates 25d and 25e, so that the wafer W and the edge ring ER are electrostatically attracted to and held on the electrostatic chuck 25. Then, the high frequency voltages from the high frequency power supplies 21-1 and 21-2 are applied to the susceptor 11. As a result, the processing gas discharged from the shower head 24 is excited into plasma, and a surface of the wafer W is etched by radicals and ions generated by this plasma.

[Configuration of Edge Ring ER]

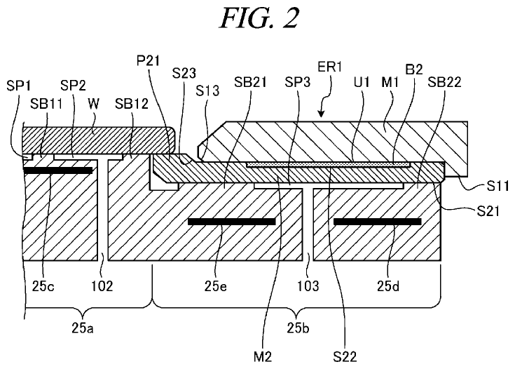

Now, a configuration of the edge ring ER will be described with reference to FIG. 2. FIG. 2 is a diagram illustrating an example configuration of the edge ring according to the present exemplary embodiment. An edge ring ER1 shown in FIG. 2 corresponds to the edge ring ER of FIG. 1.

As shown in FIG. 2, the edge ring ER1 is formed by bonding a first member M1 of an annular shape and a second member M2 of an annular shape with an adhesive layer B2 therebetween. The first member M1 is made of a first material having plasma resistance. The second member M2 is made of a second material different from the first material, for example, one having lower plasma resistance than the first material. Further, the second member M2 may be made of a second material having lower rigidity than the first material. In such a case, the second material forming the second member M2 may have higher flexibility than the first material forming the first member M1. The first material forming the first member M1 may be silicon carbide (SiC), tungsten carbide (WC), magnesium oxide (MgO), or yttria (Y₂O₃). The second material forming the second member M2 may be silicon (Si). Here, however, it should be noted that the first material and the second material are not limited to the mentioned examples.

The first member M1 is formed to cover the second member M2 on the outer peripheral side thereof, and to face a protrusion P21 of the second member M2 to be described later on the inner peripheral side thereof. The first member M1 has an inclined portion S13 at a lower portion of an inner peripheral side surface thereof. The inclined portion S13 is an example of a first inclined portion. The inclined portion S13 is formed by performing C-chamfering on a lower corner of the inner peripheral side surface of the first member M1. In addition, although this C-chamfering is performed to cut the corner at an inclination angle of 45 degrees, the inclination angle may not be limited thereto as long as the inclined portion S13 is made substantially parallel to an inclined portion S23 of the second member M2 to be described later which faces the inclined portion S13. Moreover, an upper portion of the inner peripheral side surface of the first member M1 is also chamfered at a larger inclination angle than the inclined portion S13, thus having an inclined shape.

The second member M2 is provided under the first member M1, and the protrusion P21 is provided at an upper portion of the inner peripheral side thereof. The protrusion P21 is provided closer to the wafer W than the inner peripheral side surface of the first member M1. The inclined portion S23 of the protrusion P21 on the outer peripheral side thereof faces the inclined portion S13 of the first member M1. The inclined portion S23 is an example of a second inclined portion. Desirably, the inclination portion S23 has an inclination angle that allows the inclined portion S23 to be substantially parallel to the inclined portion S13. That is, on a cross section in a vertical direction, a gap (hereinafter, referred to as an inclined gap) exists between the inclined portion S13 of the first member M1 and the inclined portion S23 of the second member M2, and a diagonally upper portion of this gap is opened toward a center of the wafer W. A bottom surface S21 of the second member M2 is in contact with the top surface of the outer peripheral portion 25b of the electrostatic chuck 25.

A recess having a depth of, for example, about 40 μm is formed in a top surface S22 of the second member M2, and the adhesive layer B2 is provided in this recess between a bottom surface U1 of the first member M1 and the second member M2. The adhesive layer B2 contains, for example, a silicon-based adhesive. In addition, the adhesive layer B2 may further contain a conductive filler. When the adhesive layer B2 contains the conductive filler, thermal conductivity between the first member M1 and the second member M2 is improved. Alumina, for example, may be used as an example of the conductive filler.

While an upper portion of an outer peripheral side surface of the second member M2 is covered with the first member M1, a lower portion thereof is not covered with the first member M1 because a bottom surface S11 of the first member M1 is located higher than the bottom surface S21 of the second member M2. For the reason, only the second member M2 in the first member M1 and the second member M2 is in contact with the top surface of the outer peripheral portion 25b of the electrostatic chuck 25. Accordingly, when the second material having lower rigidity than the first material is used as the second member M2, the adhesivity of the edge ring ER1 to the electrostatic chuck 25 can be further improved when the edge ring ER1 is attracted to the electrostatic chuck 25 electrostatically.

The central portion 25a of the electrostatic chuck 25 is provided with seal bands SB11 and SB12 each having an annular protrusion shape, and the wafer W is supported on the central portion 25a by the seal bands SB11 and SB12. Accordingly, spaces SP1 and SP2 corresponding to the height of the seal bands SB11 and SB12 are formed between the top surface of the central portion 25a and the bottom surface of the wafer W. Since the spaces SP1 and SP2 are connected to the gas inlet hole 102, the heat transfer gas supplied from the heat transfer gas supply 35 is introduced into the spaces SP1 and SP2 through the gas inlet hole 102.

Further, the outer peripheral portion 25b of the electrostatic chuck 25 is provided with seal bands SB21 and SB22 each having an annular protrusion shape, and the edge ring ER1 is supported on the outer peripheral portion 25b by the seal bands SB21 and SB22. Accordingly, a space SP3 corresponding to the height of the seal bands SB21 and SB22 is formed between the top surface of the outer peripheral portion 25b and the bottom surface S21 of the second member M2. Since the space SP3 is connected to the gas inlet hole 103, the heat transfer gas supplied from the heat transfer gas supply 35 is introduced into the space SP3 through the gas inlet hole 103.

Although the above exemplary embodiment has been described for the example where the first member M1 and the second member M2 are bonded to each other by using the adhesive layer B2 therebetween, the first member M1 and the second member M2 may be joined by diffusion bonding. In addition, the first member M1 and the second member M2 may be formed using a 3D printer.

[Reaction Product in Gap Between First Member and Second Member]

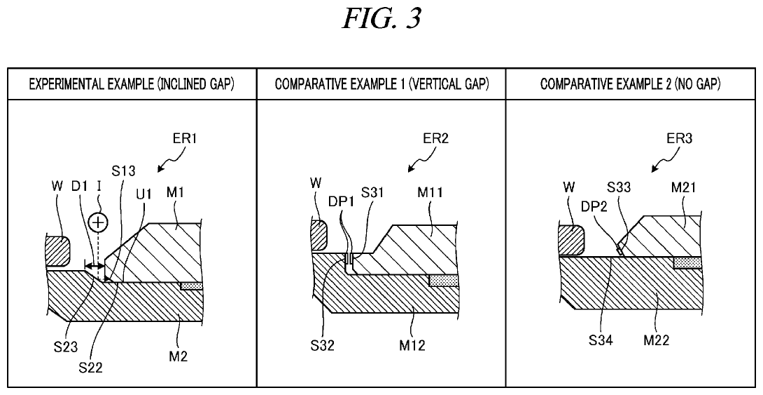

Next, adhesion of the reaction product in the gap between the first member and the second member on the inner peripheral side will be discussed with reference to FIG. 3. FIG. 3 is a diagram showing examples of the gap between the first member and the second member on the inner peripheral side in an experimental example and comparative examples. In FIG. 3, the inclined gap in the edge ring ER1 according to the present exemplary embodiment is demonstrated as the experimental example. Further, a comparative example 1 in which a gap between the first member and the second member is formed in a vertical direction, that is, a longitudinal direction (hereinafter referred to as a vertical gap), and a comparative example 2 in which there exists no gap between the first member and the second member (hereinafter referred to as “no gap”) will be described together.

First, in the edge ring ER1 of the experimental example, a gap of a distance D1 is present between the inner peripheral side surface of the first member M1 and an uppermost portion of the inclined portion S23 of the second member M2 at an inner peripheral boundary portion between the first member M1 and the second member M2. Further, the bottom surface U1 of the first member M1 in contact with the inclined portion S13 and the top surface S22 of the second member M2 in contact with a lowermost portion of the inclined portion S23 are in contact with each other. Here, assume that the distance D1 is, e.g., 0.4 mm. In addition, it is also assumed that an end portion of the wafer W is not interfered with the inclined portion S23. At this time, the reaction product adheres to the inclined portion S13 and the inclined portion S23, but the reaction product adhering to the inclined portion S23 is sputtered by ions I coming from above. Further, if the ions I collide with the inclined portion S23, the ions I bounce off to collide with the inclined portion S13, so that the reaction product adhering to the inclined portion S13 is also sputtered. That is, the adhesion of the reaction product to the inclined portion S13 and the inclined portion S23 is reduced.

In an edge ring ER2 of the comparative example 1, reaction products DP1 adhering to mutually facing surfaces S31 and S32 in the vertical gap between a first member M11 and a second member M12 are difficult to sputter by the ions as the surfaces S31 and S32 are surfaces substantially parallel to trajectories of the ions coming from above. Accordingly, the reaction products DP1 adhering to the surfaces S31 and S32 are deposited with a lapse of a plasma processing time and then peeled off later, resulting in particle generation.

In an edge ring ER3 of the comparative example 2, a reaction product DP2 adheres to a C-chamfered inclined portion S33 at a lower portion of an inner peripheral side surface of the first member M21. Ions coming from above bounce off a top surface S34 of a second member M22 between a first member M21 and the wafer W. Since, however, the top surface S34 is substantially horizontal, there are few ions colliding with the inclined portion S33, so the reaction product DP2 is difficult to sputter by the ions. For this reason, the reaction product DP2 adhering to the inclined portion S33 is deposited with the lapse of the plasma processing time and peeled off later, resulting in the particle generation.

### Experimental Results

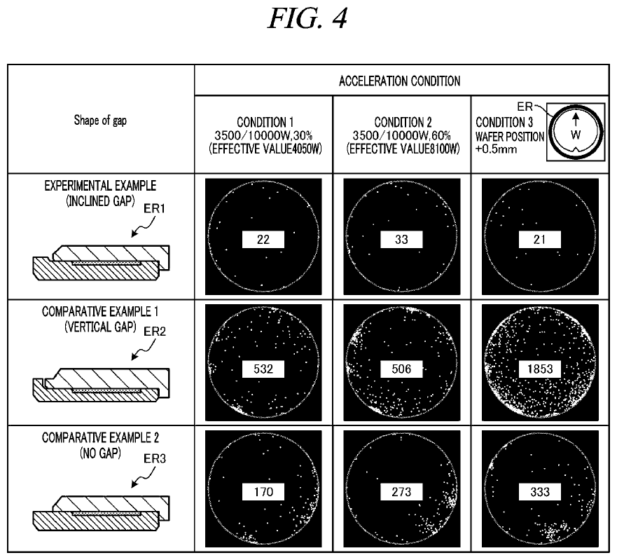

Now, results of conducting acceleration experiments for the experimental example and the comparative examples 1 and 2 shown in FIG. 3 will be described with reference to FIG. 4. FIG. 4 is a diagram showing experimental results in the experimental example and the comparative examples. In FIG. 3, conditions 1 to 3 are set as acceleration conditions. Under the condition 1, the output of the high frequency power supply 21-1 for plasma formation and the duty ratio are set to be 10000 W and 30%, and the output of the high frequency power supply 21-2 for ion attraction and the duty ratio are set to be 3500 W and 30%. That is, in the condition 1, the effective value of the high frequency power is set to be 4050 W. Under the condition 2, the output of the high frequency power supply 21-1 for plasma formation and the duty ratio are set to be 10000 W and 60%, and the output of the high frequency power supply 21-2 for ion attraction and the duty ratio are set to be 3500 W and 60%. That is, in the condition 2, the effective value of the high frequency power is set to be 8100 W.

Under the condition 3, the outputs of the high frequency power supply 21-1 and the high frequency power supply 21-2 are set to be equal to those of the condition 1, and a wafer position is shifted to the upper side (+side) by 0.5 mm so as to enlarge a gap on a notch side (lower side in FIG. 4) of the wafer W. Further, under the conditions 1 to 3, the plasma processing time (etching time) is set to be 50 hours.

In the edge ring ER1 of the experimental example, the number of particles is found to be ‘22’ under the condition 1, ‘33’ under the condition 2, and ‘21’ under the condition 3. Meanwhile, in the edge ring ER2 of the comparative example 1, the number of particles is found to be ‘532’ under the condition 1, ‘506’ under the condition 2, and ‘1853’ under the condition 3. In the edge ring ER3 of the comparative example 2, the number of particles is ‘170’ under the condition 1, ‘273’ under the condition 2, and ‘333 particles’ under the condition 3. As can be seen from these results, in the edge rings ER2 and ER3 of the comparative examples 1 and 2, the number of the particles are found to increase under all of the conditions 1 to 3, as compared to the edge ring ER1 of the experimental example. On the other hand, in the edge ring ER1 of the experimental example, the number of the particles hardly changes under the conditions 1 to 3, and it can be suppressed to 40 or less. That is, the edge ring ER1 of the experimental example can suppress the particle generation even when the output of high frequency power is changed or the position of wafer W is shifted to one side.

[Effect of Processing Precision of Inclined Gap]

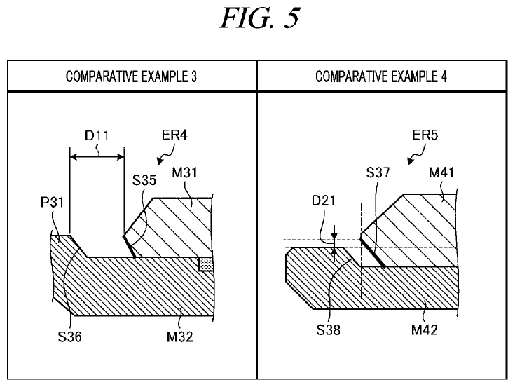

Now, an effect of processing precision in an inclined gap will be explained with reference to FIG. 5. FIG. 5 is a diagram showing comparative examples regarding the processing precision. FIG. 5 illustrates a comparative example 3 where an inclined gap between a first member M31 and a second member M32 is wide, and a comparative example 4 where an inclined portion S37 of a first member M41 is protruded higher than a top surface of a protrusion of a second member M42.

In an edge ring ER4 of the comparative example 3, a protrusion P31 of the second member M32 is far from an inclined portion S35 of the first member M31, that is, an inclined gap is enlarged as a distance D11 corresponding to the distance D1 of the edge ring ER1 becomes larger than the distance D1. Specifically, in the edge ring ER4, the distance D11 is set to be 1 mm. In this case, since ions bounced off an inclined portion S36 of the second member M32 are less likely to collide with the inclined portion S35 of the first member M31, a reaction product adhering to the inclined portion S35 may increase. Thus, it is desirable that the distance of D1 in the edge ring ER1 is less than 1 mm.

In an edge ring ER5 of the comparative example 4, the area of the inclined portion S37 of the first member M41 is larger than an area of an inclined portion S38 of the second member M42, so that the a top surface of the inclined portion S37 of the first member M41 is protruded higher than the top surface of the protrusion of the second member M42 by a distance D21. In this case, since ions bounced off the inclined portion S38 of the second member M42 are less likely to collide with the inclined portion S37 within the range of the distance D21, a reaction products that are attached in the range of the distance D21 may be increased. As can be seen from the comparative examples 3 and 4, if the processing precision of the edge ring ER is poor, the reaction product adheres to the inclined gap. In view of this, it is found that the edge ring ER that satisfies the required processing precision has an effect of suppressing the adhesion of the reaction product, thus capable of suppressing the particle generation.

As described above, according to the present exemplary embodiment, the edge ring ER, which is disposed around the processing target substrate (wafer W), includes the first member M1 having the annular shape and the second member M2 having the annular shape. The first member M1 is made of the first material and has the first inclined portion (inclined portion S13) at the lower portion of the inner peripheral side surface thereof, and the second member M2 is made of the second material different from the first material, and has the second inclined portion (inclined portion S23) facing the first inclined portion. The second member M2 is disposed under the first member M1. With this configuration, the replacement frequency of the edge ring ER can be reduced, and leakage of the heat transfer gas and generation of particles can be suppressed.

Further, according to the present exemplary embodiment, the second member M2 has the protrusion P21 at the upper portion of the inner peripheral side thereof, and the protrusion P21 is provided with the second inclined portion. As a result, the inclined gap can be provided between the first member M1 and the second member M2.

Moreover, according to the present exemplary embodiment, the protrusion P21 is positioned closer to the processing target substrate than the inner peripheral side surface of the first member M1. As a result, the inclined gap can be provided between the first member M1 and the second member M2.

Further, according to the present exemplary embodiment, a horizontal distance between the first inclined portion and the second inclined portion is less than 1 mm. As a result, adhesion of the reaction product to the first inclined portion can be suppressed.

Furthermore, according to the present exemplary embodiment, the second material has lower rigidity than the first material. As a result, leakage of the heat transfer gas can be suppressed.

In addition, according to the present exemplary embodiment, the first material is silicon carbide, tungsten carbide, magnesium oxide, or yttria, and the second material is silicon. As a result, the replacement frequency of the edge ring ER can be reduced, and the leakage of the heat transfer gas can be suppressed.

Moreover, according to the present exemplary embodiment, the first member M1 and the second member M2 are bonded to each other with the adhesive layer B2 therebetween. As a result, the replacement frequency of the edge ring ER can be reduced, and the leakage of the heat transfer gas can be suppressed.

Furthermore, according to the present exemplary embodiment, the adhesive layer B2 contains a silicon-based adhesive. As a result, the first member M1 and the second member M2 having different rigidity can be joined to each other.

Further, according to the present exemplary embodiment, the adhesive layer B2 further includes the conductive filler. As a result, thermal conductivity between the first member M1 and the second member M2 can be improved.

Additionally, according to the present exemplary embodiment, the adhesive layer B2 is provided in the recess formed in the top surface of the second member M2. As a result, it is possible to prevent the adhesive layer B2 from being exposed to plasma.

It should be noted that the above-described exemplary embodiment is illustrative in all aspects and is not anyway limiting. The above-described exemplary embodiment may be omitted, replaced and modified in various ways without departing from the scope and the spirit of claims.

For example, the edge ring according to the present disclosure may be applicable not only to a capacitively coupled plasma (CCP) apparatus, but also to various types of substrate processing apparatuses. The various types of substrate processing apparatus may include an inductively coupled plasma (ICP) processing apparatus, a plasma processing apparatus using a radial line slot antenna, a helicon wave plasma (HWP) apparatus, an electron cyclotron resonance plasma (ECR) apparatus, and the like.

Further, in the substrate processing apparatus 100 of the present exemplary embodiment, the two electrode plates for electrostatic attraction are provided in the outer peripheral portion 25b of the electrostatic chuck 25. However, the number of the electrode plates provided in the outer peripheral portion 25b for the electrostatic attraction may be, for example, only one, or more than two.

In the present disclosure, the semiconductor substrate has been demonstrated as a target of the plasma processing. However, the target of the plasma processing is not limited to the semiconductor substrate, and may be any of various kinds of substrates for use in a LCD (Liquid Crystal Display) and a FPD (Flat Panel Display), a photomask, a CD substrate, a print substrate, and so forth.

According to the exemplary embodiment, it is possible to reduce the replacement frequency of the edge ring while suppressing the leakage of the heat transfer gas and the generation of the particles.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. An edge ring disposed around a processing target substrate, comprising:
a first member of an annular shape, which is made of a first material and has a first inclined portion at a lower portion of an inner peripheral side surface thereof; and
a second member of an annular shape, which is made of a second material different from the first material and has a second inclined portion facing the first inclined portion, the second member being provided under the first member.

2. The edge ring of claim 1,
wherein the second member has a protrusion at an upper portion of an inner peripheral side thereof, and
the protrusion is provided with the second inclined portion.

3. The edge ring of claim 2,
wherein the protrusion is provided closer to the processing target substrate than the inner peripheral side surface of the first member.

4. The edge ring of claim 1,
wherein a horizontal distance between the first inclined portion and the second inclined portion is less than 1 mm.

5. The edge ring of claim 1,
wherein the second material has lower rigidity than the first material.

6. The edge ring of claim 1,
wherein the first material is silicon carbide, tungsten carbide, magnesium oxide, or yttria, and
the second material is silicon.

7. The edge ring of claim 1,
wherein the first member and the second member are bonded to each other with an adhesive layer therebetween.

8. The edge ring of claim 7,
wherein the adhesive layer contains a silicon-based adhesive.

9. The edge ring of claim 7,
wherein the adhesive layer contains a conductive filler.

10. The edge ring of claim 7,
wherein the adhesive layer is provided in a recess formed in a top surface of the second member.

11. A substrate processing apparatus, comprising:
a processing vessel in which a processing space is provided;
a placing table provided within the processing vessel to hold a processing target substrate; and
an edge ring disposed to surround the processing target substrate,
wherein the edge ring comprises:
a first member of an annular shape, which is made of a first material and has a first inclined portion at a lower portion of an inner peripheral side surface thereof; and
a second member of an annular shape, which is made of a second material different from the first material and has a second inclined portion facing the first inclined portion, the second member being provided under the first member.
